(19) United States
(12) Patent Application Publication
(10) Pub. No.: US 2017/0033239 A1
(43) Pub. Date: Feb. 2, 2017

(54) SEMICONDUCTOR DEVICE AND IMAGING DEVICE

(71) Applicant: Kabushiki Kaisha Toshiba, Minato-ku (JP)

(72) Inventors: Shintaro NAKANO, Kawasaki (JP); Nobuyoshi SAITO, Ota (JP); Kentaro MIURA, Kawasaki (JP); Yuya MAEDA, Kawasaki (JP)

(73) Assignee: Kabushiki Kaisha Toshiba, Minato-ku (JP)

(21) Appl. No.: 15/229,919

(22) Filed: Aug. 5, 2016

Related U.S. Application Data
(63) Continuation of application No. PCT/JP2014/072806, filed on Aug. 29, 2014.

(30) Foreign Application Priority Data
Feb. 6, 2014 (JP) 2014-021752

(51) Int. Cl. H01L 29/786; H01L 27/146; H01L 29/66; H01L 29/24; H01L 29/51

(52) U.S. Cl. CPC H01L 29/78693; H01L 29/78696; H01L 29/247; H01L 29/78648; H01L 29/518; H01L 29/66969; H01L 27/14616

(57) ABSTRACT

A semiconductor device includes a substrate having a major surface and a thin film transistor on the substrate. The thin film transistor includes an oxynitride semiconductor layer, first and second conductive layers, a first gate electrode and a first insulating layer. The oxynitride semiconductor layer includes a first portion electrically connected to the first conductive layer, a second portion electrically connected to the second conductive layer, and a third portion provided between the first and second portions. The oxynitride semiconductor layer includes indium, gallium, zinc, and nitrogen, a nitrogen content of the oxynitride semiconductor layer being 2 atomic % or less, and a gallium content of the oxynitride semiconductor layer is more than the nitrogen content. The first gate electrode is separated from the third portion in a direction intersecting the first direction; and the first insulating layer is provided between the third portion and the first gate electrode.

### CROSS-REFERENCE TO RELATED APPLICATIONS

This is a continuation application of International Application PCT/JP2014/072806, filed on Aug. 29, 2014; the entire contents of which are incorporated herein by reference.

### FIELD

Embodiments are generally related to a semiconductor device and an imaging device.

### BACKGROUND

A semiconductor device that includes a functional element such as an imaging element, an arithmetic element, an amplifying element, a memory element, or the like is formed on, for example, a silicon substrate, etc. It is desirable to improve the functions, while increasing the integration of such semiconductor devices.

### BRIEF DESCRIPTION OF THE DRAWINGS

FIG. 1 is a schematic cross-sectional view showing a semiconductor device according to a first embodiment;

FIG. 2 is a graph showing characteristics of the semiconductor device;

FIG. 3 is a graph showing characteristics of the semiconductor device;

FIG. 4 is a graph showing characteristics of the semiconductor device;

FIG. 5 is a graph showing characteristics of the semiconductor device;

FIG. 6 is a schematic cross-sectional view showing a portion of a semiconductor device according to a second embodiment;

FIG. 7 is a plan view showing a portion of the semiconductor device according to the second embodiment;

FIG. 8 is a schematic cross-sectional view showing portions of other semiconductor devices according to the second embodiment;

FIG. 9 is a schematic cross-sectional view showing portions of other semiconductor devices according to the second embodiment;

FIG. 10 is a schematic cross-sectional view showing portions of other semiconductor devices according to the second embodiment;

FIG. 11 is a schematic cross-sectional view showing portions of other semiconductor devices according to the second embodiment;

FIG. 12 is a schematic cross-sectional view showing a semiconductor device according to a third embodiment; and

FIG. 13 is a flowchart showing a method for manufacturing a semiconductor device according to a fourth embodiment;

FIG. 14A is a schematic cross-sectional view in order of processes, showing the method for manufacturing the semiconductor device according to the fourth embodiment;

FIG. 14B is a schematic cross-sectional view in order of processes, showing the method for manufacturing the semiconductor device according to the fourth embodiment;

FIG. 14C is a schematic cross-sectional view in order of processes, showing the method for manufacturing the semiconductor device according to the fourth embodiment;

FIG. 15 is a flowchart showing a method for manufacturing a semiconductor device according to a fifth embodiment;

FIG. 16A is a schematic cross-sectional view in order of processes, showing the method for manufacturing the semiconductor device according to the fifth embodiment;

FIG. 16B is a schematic cross-sectional view in order of processes, showing the method for manufacturing the semiconductor device according to the fifth embodiment; and

FIG. 16C is a schematic cross-sectional view in order of processes, showing the method for manufacturing the semiconductor device according to the fifth embodiment.

### DETAILED DESCRIPTION

According to one embodiment, a semiconductor device includes a substrate having a major surface and a thin film transistor provided on the substrate. The thin film transistor includes an oxynitride semiconductor layer, a first conductive layer, a second conductive layer, a first gate electrode and a first insulating layer. The oxynitride semiconductor layer includes a first portion, a second portion, and a third portion. The second portion is separated from the first portion in a first direction parallel to the major surface; and the third portion is provided between the first portion and the second portion. The oxynitride semiconductor layer includes indium, gallium, zinc, and nitrogen, a nitrogen content of the oxynitride semiconductor layer being 2 atomic % or less, and a gallium content of the oxynitride semiconductor layer is more than the nitrogen content. The first conductive layer electrically is connected to the first portion; and the second conductive layer is electrically connected to the second portion. The first gate electrode is separated from the third portion in a second direction perpendicular to the major surface; and the first insulating layer is provided between the third portion and the first gate electrode.

Embodiments will now be described with reference to the drawings. It should be noted that the drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. The same portions inside the drawings are marked with the same numerals; a detailed description is omitted as appropriate.

### First Embodiment

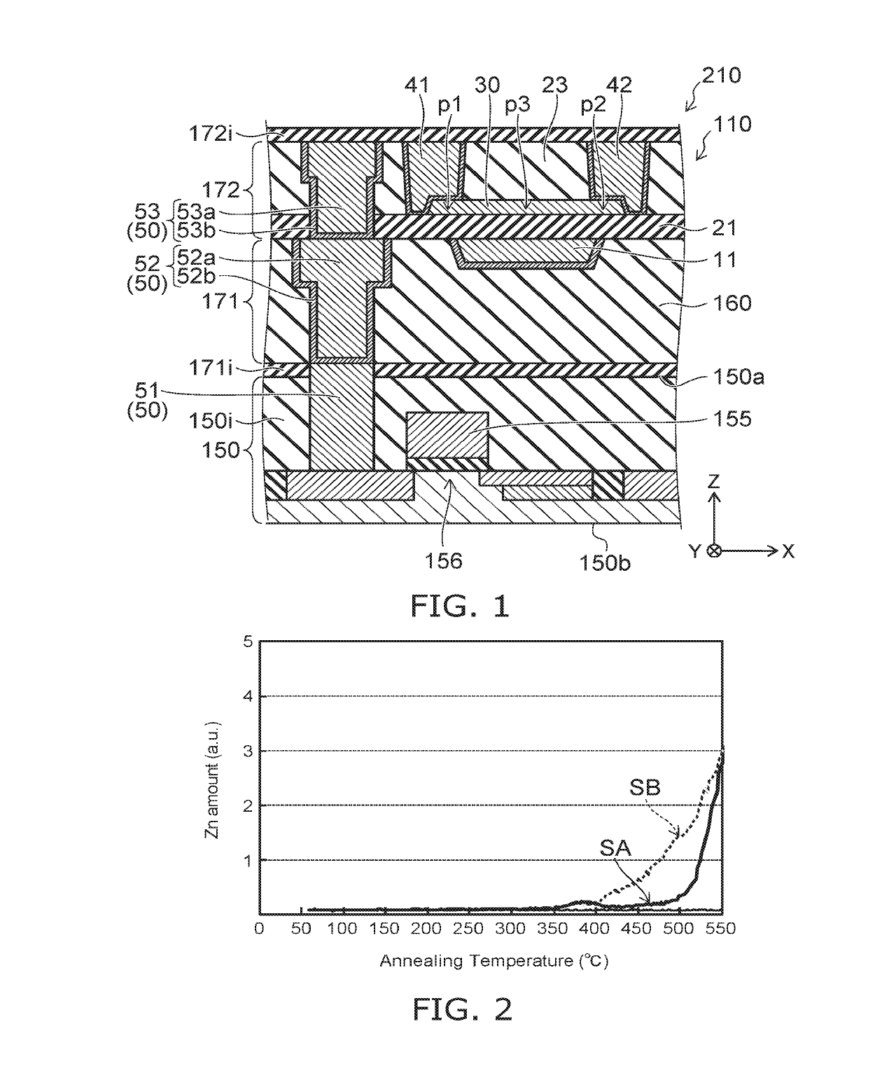

FIG. 1 is a schematic cross-sectional view showing a semiconductor device according to a first embodiment.

As shown in FIG. 1, the semiconductor device 210 according to the embodiment includes a substrate 150, a foundation insulating layer 160, and a thin film transistor 110.

The substrate 150 includes a functional element 155. For example, a semiconductor substrate such as a silicon substrate, etc may be used for the substrate 150. An SOI substrate may be used as the substrate 150. The substrate 150 has an upper surface 150a. The functional element 155 includes, for example, an imaging unit 156 provided at a lower surface 150b of the substrate 150. The substrate 150 further includes an inter-layer insulating layer 150i that covers the functional element 155. The upper surface of the inter-layer insulating layer 150i corresponds to the upper surface 150a of the substrate 150.

The foundation insulating layer 160 is provided on the upper surface 150a of the substrate 150.

In this specification, the “state of being provided on” includes not only the state of being disposed directly thereon, but also the state in which another component is inserted therebetween.

In the example, the semiconductor device 210 includes the substrate 150, a first interconnect layer 171 provided on the substrate 150, and a second interconnect layer 172 provided on the first interconnect layer 171. The foundation insulating layer 160 is included in the first interconnect layer 171. In the example, a first inter-layer insulating layer 171i is provided between the substrate 150 and the first interconnect layer 171, i.e., between the substrate 150 and the foundation insulating layer 160.

A direction perpendicular to the upper surface 150a of the substrate 150 is taken as a Z-axis direction. One direction perpendicular to the Z-axis direction is taken as an X-axis direction. A direction perpendicular to the Z-axis direction and intersecting the X-axis direction is taken as a Y-axis direction.

For example, the thin film transistor 110 is provided inside the first interconnect layer 171 and the second interconnect layer 172. The thin film transistor 110 is provided on the foundation insulating layer 160.

The thin film transistor 110 includes a gate electrode 11, a first insulating layer 21, a semiconductor layer 30, a first conductive layer 41, a second conductive layer 42, and an insulating layer 23.

The gate electrode 11 is provided on a portion of the foundation insulating layer 160. For example, the lower surface and side surface of the gate electrode 11 are surrounded with the foundation insulating layer 160. Except for the upper surface of the gate electrode 11, the gate electrode 11 is filled into the foundation insulating layer 160. In other words, the gate electrode 11 and the foundation insulating layer 160 have a damascene configuration.

The first insulating layer 21 covers the gate electrode 11 and the foundation insulating layer 160. The first insulating layer 21 includes, for example, silicon and nitrogen. In other words, the first insulating layer 21 includes a compound including silicon and nitrogen. The first insulating layer 21 includes, for example, silicon nitride or silicon oxynitride.

The semiconductor layer 30 is provided on a portion of the first insulating layer 21 and contacts the portion of the first insulating layer 21. The semiconductor layer 30 is an oxynitride that includes indium (In), gallium (Ga), and zinc (Zn).

The semiconductor layer 30 is an oxynitride semiconductor layer. For example, the semiconductor layer 30 has an amorphous structure. The semiconductor layer 30 may include a portion that is polycrystalline.

The semiconductor layer 30 includes a first portion p1 and a second portion p2. The second portion p2 is provided to be separated from the first portion p1 in the X-axis direction (a first direction). The semiconductor layer 30 includes a third portion p3 provided between the first portion p1 and the second portion p2.

The gate electrode 11 is provided to be separated from the third portion p3 in the Z-axis direction intersecting the X-axis direction. The first insulating layer 21 is provided between the third portion p3 and the gate electrode 11.

The first conductive layer 41 is provided on a portion of the semiconductor layer 30 and is electrically connected to the first portion p1. The second conductive layer 42 is provided on one other portion of the semiconductor layer 30 and is electrically connected to the second portion p2. The first conductive layer 41 and the second conductive layer 42 are arranged in the X-direction. The first conductive layer 41 is one of a source electrode or a drain electrode. The second conductive layer 42 is the other of the source electrode or the drain electrode.

The insulating layer 23 covers the semiconductor layer 30. The insulating layer 23 includes oxygen and at least one of silicon (Si), aluminum (Al), titanium (Ti), tantalum (Ta), hafnium (Hf), and zirconium (Zr). In other words, the insulating layer 23 includes a compound including oxygen and at least one of Si, Al, Ti, Ta, Hf, and Zr.

An interconnect 50 is provided in the example. In the example, the interconnect 50 includes a first interconnect 51, a second interconnect 52, and a third interconnect 53. Each of the first interconnect 51, the second interconnect 52, and the third interconnect 53 extends along the Z-axis direction. The first interconnect 51 pierces the inter-layer insulating layer 150i of the substrate 150 along the Z-axis direction. For example, one end of the first interconnect 51 is electrically connected to the functional element 155.

In this specification, the “state of being electrically connected” includes the state in which two conductors are in direct contact, the state in which a current flows in two conductors via another conductor, and the state in which an electrical element such as a switching element or the like is inserted between two conductors and a state in which a current flows is formable.

The second interconnect 52 pierces the foundation insulating layer 160 along the Z-axis direction and is electrically connected to the first interconnect 51.

The third interconnect 53 pierces the first insulating layer 21 and the insulating layer 23 along the Z-axis direction and is electrically connected to the second interconnect 52. For example, one end of the third interconnect 53 is electrically connected to the thin film transistor 110. For example, the one end of the third interconnect 53 may be connected to, for example, at least one of the first conductive layer 41 and the second conductive layer 42.

For example, the first interconnect 51 and the second interconnect 52 may be provided without providing the third interconnect 53. In such a case, one end of the second interconnect 52 may be connected to the first gate electrode 11 of the thin film transistor 110.

Thus, the interconnect 50 pierces at least the foundation insulating layer 160 along a direction (the Z-axis direction) intersecting the upper surface 150a of the substrate 150. For example, the interconnect 50 is connected to at least one of the first gate electrode 11, the first conductive layer 41, and the second conductive layer 42. For example, the interconnect 50 electrically connects the at least one of the first gate electrode 11, the first conductive layer 41, and the second conductive layer 42 to the functional element 155.

For example, the interconnect 50 pierces the first interconnect layer 171 along the Z-axis direction. The interconnect 50 further pierces the second interconnect layer 172 along the Z-axis direction.

In the example, the first interconnect layer 171 includes the foundation insulating layer 160, the first gate electrode 11, and the second interconnect 52. In the example, the second interconnect layer 172 includes the first insulating layer 21, the semiconductor layer 30, the first conductive layer 41, the second conductive layer 42, the insulating layer 23, and the third interconnect 53. An upper layer insulating layer 172i may be further provided on the second interconnect layer 172.

In the example, the second interconnect 52 and the third interconnect 53 have multilayered structures.

For example, the second interconnect 52 includes an upper layer 52a for the second interconnect 52, and a lower layer 52b for the second interconnect 52 that is stacked with the upper layer 52a. For example, the lower layer 52b is disposed between the upper layer 52a and the foundation insulating layer 160. The upper layer 52a includes, for example, at least one metal of aluminum (Al), copper (Cu), tungsten (W), tantalum (Ta), molybdenum (Mo), and titanium (Ti). The lower layer 52b includes, for example, at least one of tantalum, tantalum nitride (TaN), and titanium nitride (TiN). The lower layer 52b for the second interconnect 52 includes a material that is different from the upper layer 52a for the second interconnect 52.

For example, the third interconnect 53 includes an upper layer 53a for the third interconnect 53, and a lower layer 53b for the third interconnect 53 that is stacked with the upper layer 53a. For example, the lower layer 53b is disposed between the upper layer 53a and the third insulating layer 23. The upper layer 53a includes, for example, at least one metal of Al, Cu, W, Ta, Mo, and Ti. The lower layer 53b includes, for example, at least one of Ta, TaN, and TiN. The lower layer 53b for the third interconnect 53 includes a material that is different from the upper layer 53a for the third interconnect 53.

For example, the semiconductor device 210 according to the embodiment is used in an imaging device. The semiconductor device 210 includes, for example, a photodiode and a transfer transistor formed by a CMOS process on a silicon substrate. The photodiode is, for example, the imaging unit 156; and the transfer transistor corresponds to the functional element 155. The interconnect layers 171 and 172 are stacked on the substrate 150 including the photodiode and the transfer transistor. The thin film transistor 110 that includes the oxynitride semiconductor layer is provided in the interconnect layers 171 and 172.

In the manufacturing processes of the semiconductor device 210 as described below, after forming the interconnect layers 171 and 172 including the thin film transistor 110, heat treatment is performed to recover the function of the transfer transistor that degraded in the interconnect process. The temperature of the heat treatment is, for example, 420° C. Due to the heat treatment, there are cases where the sheet resistance of the oxynitride semiconductor changes and the characteristics of the thin film transistor degrade.

The inventor of the application discovered conditions at which it is possible to suppress the degradation of the thin film transistor in such a heat treatment process.

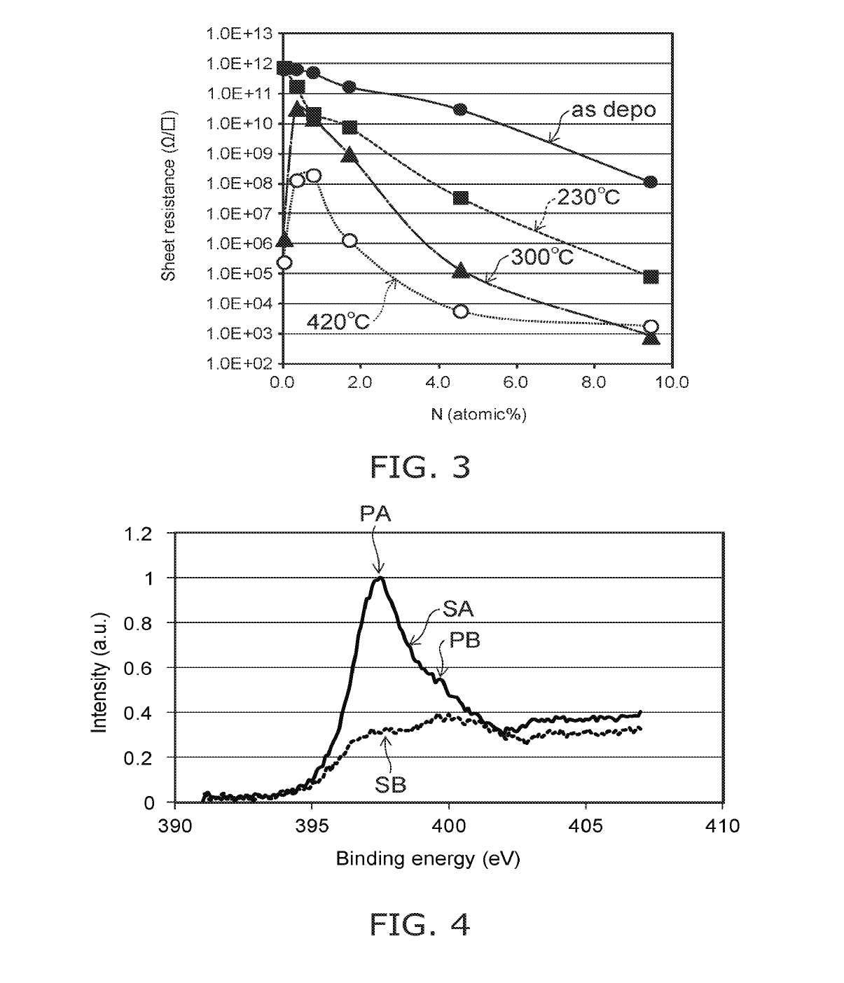

FIG. 2 and FIG. 3 are graphs of characteristics of the semiconductor device. Specifically, the characteristics for the heat treatment of the oxynitride semiconductor used in the semiconductor layer 30 are shown.

FIG. 2 is a graph of the amount of zinc desorbing from an oxynitride semiconductor SA and an oxide semiconductor SB due to the heat treatment. The horizontal axis is the heat treatment temperature (annealing temperature); and the vertical axis is the desorption amount of zinc. The oxide semiconductor SB does not include nitrogen. The composition ratios of In, Ga, and Zn are the same in the oxynitride semiconductor SA and the oxide semiconductor SB shown in the figure.

It can be seen from FIG. 2 that in the oxide semiconductor SB, the desorption amount of zinc increases gradually as the heat treatment temperature increases in the temperature range of 400° C. or more. On the other hand, in the oxynitride semiconductor SA, the desorption of zinc is suppressed up to the vicinity of 500° C. Thus, in the oxynitride semiconductor, it is possible to suppress the zinc desorption for heat treatment temperatures up to 500° C.; and, for example, the change of the transistor characteristics can be suppressed.

FIG. 3 is a graph of the heat treatment temperature dependence of the sheet resistance of the oxynitride semiconductor. The horizontal axis is the content ratio (atomic %) of nitrogen included in the oxynitride semiconductor. The vertical axis is the sheet resistance of the oxynitride semiconductor. The dependence of the sheet resistance with respect to the nitrogen content ratio is shown using the heat treatment temperature as a parameter. Here, the nitrogen content ratio is the proportion of the number of nitrogen atoms to the sum of the number of indium atoms, the number of gallium atoms, the number of zinc atoms, the number of oxygen atoms, and the number of nitrogen atoms included in the oxynitride semiconductor.

It can be seen from the characteristics shown in FIG. 3 that the sheet resistance of the oxynitride semiconductor has a peak in the region where the nitrogen content ratio is 1 atomic % or less; and the sheet resistance decreases as the nitrogen content ratio increases. Also, the sheet resistance decreases as the heat treatment temperature increases.

For the characteristic of the heat treatment temperature of 420° C. shown in FIG. 3, for example, the sheet resistance of the oxynitride semiconductor can be maintained at 5×10⁵Ω/□ or more if the nitrogen content is set to be 2 atomic % or less. In the range of the nitrogen content of 0.1 atomic % to 1.6 atomic %, the sheet resistance can be maintained at 1×10⁶Ω/□ or more. In the range of the nitrogen content of 0.2 atomic % to 1.2 atomic %, the sheet resistance can be maintained at 1×10⁷Ω/□ or more.

Thus, the decrease of the sheet resistance can be suppressed by controlling the nitrogen content to be in a constant range. For example, for a heat treatment temperature at the vicinity of 400° C., it is possible to operate the thin film transistor 110 stably if the nitrogen content of the oxynitride semiconductor is set to be 2 atomic % or less. In such a case, it is favorable for the proportion of the number of nitrogen atoms to be not more than 3.3 atomic % of the sum of the number of oxygen atoms and the number of nitrogen atoms.

The sheet resistance also can be increased by increasing the content ratio of gallium in the oxynitride semiconductor. In other words, the immunity to the heat treatment recited above increases as the content ratio of gallium increases. For example, it is favorable to set the content ratio of gallium atoms to be larger than the content ratio of nitrogen atoms in the oxynitride semiconductor.

FIG. 4 shows XPS (X-ray Photoelectron Spectroscopy) analysis results of the oxynitride semiconductor SA and the oxide semiconductor SB. The horizontal axis is the binding energy between atoms; and the vertical axis is the signal strength. The measurements are implemented in the state before heat treatment of the oxynitride semiconductor SA and the oxide semiconductor SB.

In the oxynitride semiconductor SA as shown in FIG. 4, the signal strength becomes high between binding energies of 395 eV to 400 eV; and peaks PA and PB are observed. Peak PA indicates a bond of a metal and nitrogen (Metal-N); and peak PB indicates a bond of a metal, nitrogen, and oxygen (Metal-N—O). In other words, the oxynitride semiconductor in which nitrogen is doped into the oxide semiconductor IGZO includes a bond of indium and nitrogen (In—N), a bond of zinc and nitrogen (Zn—N), a bond of gallium and nitrogen (Ga—N), a bond of indium, oxygen, and nitrogen (In—O—N), a bond of zinc, oxygen, and nitrogen (Zn—O—N), and a bond of gallium, oxygen, and nitrogen (Ga—O—N).

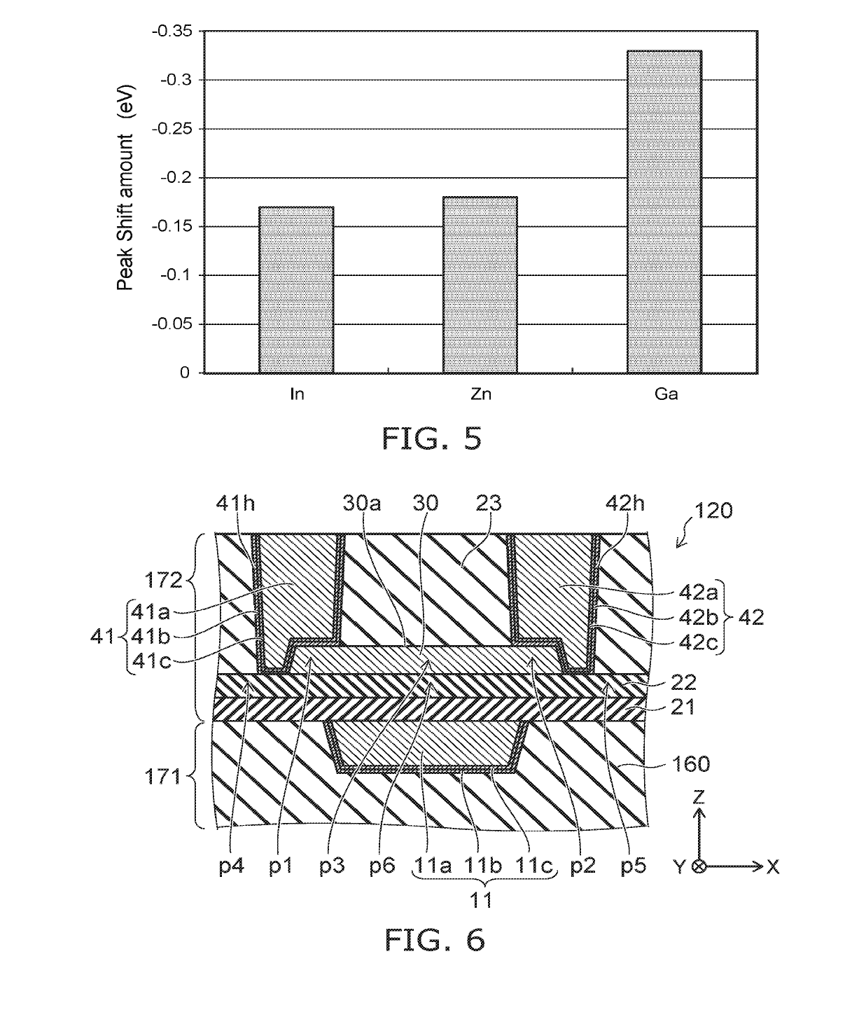

FIG. 5 is a graph of the results of Auger electron spectroscopy of the oxynitride semiconductor SA. The vertical axis of FIG. 5 is the shift amount of the Auger peak of each element before and after the heat treatment.

As shown in FIG. 5, it can be seen that the shift amount of gallium is largest. To suppress the change of the characteristics before and after the heat treatment, it can be seen from the data that it is favorable to set the content ratio of gallium to be high and to set the bond of gallium and nitrogen and the bond of gallium, oxygen, and nitrogen to be more than the bonds of indium or zinc.

Thus, in the semiconductor device 210 according to the embodiment, the thin film transistor 110 that includes the oxynitride semiconductor layer 30 is provided on the substrate 150 including the functional element 155. Thereby, the immunity of the thin film transistor 110 to the heat treatment is improved; and it is possible to operate the semiconductor device 210 stably.

Also, by using the thin film transistor, a peripheral circuit that includes an amplifier for the functional element 155 or a control transistor can be formed on the functional element 155 such as the imaging element, etc. Thereby, a smaller semiconductor device 210 is possible.

For example, the oxide semiconductor having a large surface area can be formed uniformly as a film at room temperature by sputtering. Also, a process having a temperature lower than that of a CMOS process, e.g., a process of 300° C. to 400° C., is applicable. Relatively high field effect mobility is obtained in the oxide semiconductor.

In the semiconductor device 210 used in the imaging device, by forming the peripheral circuit of the functional element 155 in the interconnect layers including the thin film transistor 110, for example, it is possible to increase the integration without reducing the surface area of the functional element 155. By ensuring the prescribed surface area projected in the Z-axis direction of the imaging unit 156 included in the functional element 155, an imaging device having the desired S/N ratio can be realized. In other words, according to the embodiment, a semiconductor device having both higher integration and improved functions can be provided.

The thin film transistor 110 is, for example, a thin film transistor having a bottom-gate structure. In the semiconductor device 210, a portion of the interconnect of the first interconnect layer 171 is used as the gate electrode 11 of the thin film transistor 110. An example of the thin film transistor 110 will be described further below.

### Second Embodiment

FIG. 6 is a schematic cross-sectional view showing a portion of a semiconductor device according to a second embodiment.

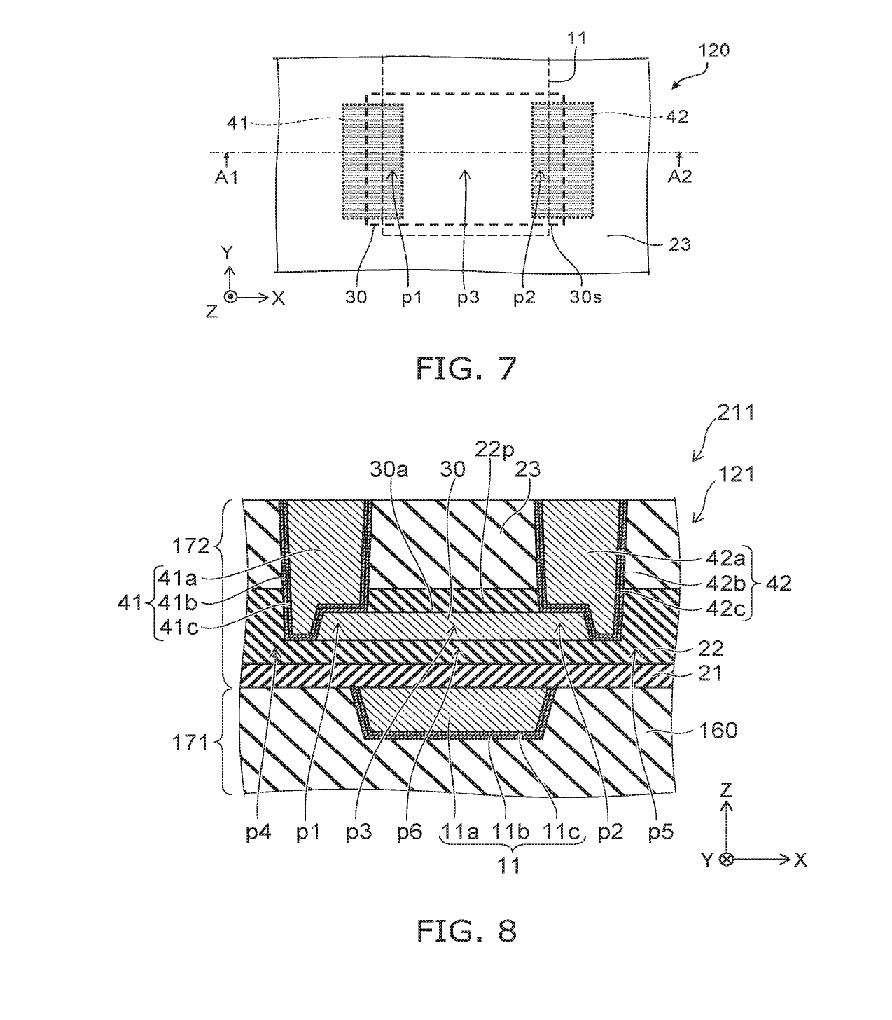

FIG. 7 is a schematic plan view showing a portion of the semiconductor device according to the second embodiment.

FIG. 6 is a line A1-A2 cross-sectional view of FIG. 7. These drawings show a thin film transistor 120 included in the semiconductor device according to the embodiment.

The thin film transistor 120 includes the first insulating layer 21 between the semiconductor layer 30 and the gate electrode 11, and further includes a second insulating layer 22 between the first insulating layer 21 and the semiconductor layer 30.

As shown in FIG. 6 and FIG. 7, the gate electrode 11 is provided on a portion of the foundation insulating layer 160. The first insulating layer 21 covers the first gate electrode 11 and the foundation insulating layer 160. The first insulating layer 21 includes a first compound including silicon and nitrogen. The second insulating layer 22 is provided on the first insulating layer 21. The second insulating layer 22 includes oxygen and at least one of Al, Ti, Ta, Hf, and Zr. In other words, the second insulating layer 22 includes a second compound including oxygen and at least one of Al, Ti, Ta, Hf, and Zr. The third insulating layer 23 that covers the semiconductor layer 30 is provided on the second insulating layer 22.

The second insulating layer 22 includes a fourth portion p4, a fifth portion p5, and a sixth portion p6. The fifth portion p5 is separated from the fourth portion p4 in the first direction (in the example, the X-axis direction) in the X-Y plane (a plane parallel to the upper surface 150a of the substrate 150). The fifth portion p5 is provided between the fourth portion p4 and the fifth portion p5. The sixth portion p6 is positioned on the first gate electrode 11. The sixth portion p6 opposes the first gate electrode 11 with the first insulating layer 21 interposed.

The semiconductor layer 30 contacts the second insulating layer 22 on the sixth portion p6. The semiconductor layer 30 includes the first portion p1, the second portion p2, and the third portion p3. The second portion p2 is separated from the first portion p1 in the first direction (the X-axis direction). The third portion p3 is provided between the first portion p1 and the second portion p2.

When projected onto the X-Y plane, the first portion p1 is disposed between the third portion p3 and the fourth portion p4. When projected onto the X-Y plane, the second portion p2 is disposed between the third portion p3 and the fifth portion p5. When projected onto the X-Y plane, the third portion p3 overlaps the sixth portion p6.

The first conductive layer 41 contacts the first portion p1 of the semiconductor layer 30. In the example, the first conductive layer 41 further contacts the fourth portion p4 of the second insulating layer 22. The second conductive layer 42 contacts the second portion p2 of the semiconductor layer 30. In the example, the second conductive layer 42 further contacts the fifth portion p5 of the second insulating layer 22.

For example, the first conductive layer 41 is formed by filling a conductive material into a first hole 41h provided in the third insulating layer 23. For example, the second conductive layer 42 is formed by filling a conductive material into a second hole 42h provided in the third insulating layer 23. The first hole 41h and the second hole 42h are separated from each other in the X-axis direction.

The third insulating layer 23 covers a portion of the semiconductor layer 30 other than the first portion p1 (the portion contacting the first conductive layer 41) and the second portion p2 (the portion contacting the second conductive layer 42). For example, the third insulating layer 23 covers an upper surface 30a of the third portion p3 of the semiconductor layer 30.

As shown in FIG. 7, the third insulating layer 23 also covers a side surface 30s of the semiconductor layer 30. The side surface 30s is a surface that intersects the X-Y plane.

Thus, in the semiconductor device 210 according to the embodiment, the first insulating layer 21 that includes silicon and nitrogen is provided to cover the gate electrode 11 and the foundation insulating layer 160 included in the first interconnect layer 171. The first insulating layer 21 includes, for example, silicon nitride (i.e., SiNₓ), etc. The first insulating layer 21 has high functionality as a protective layer.

The second insulating layer 22 contacts the semiconductor layer 30. The second insulating layer 22 includes, for example, aluminum oxide (e.g., Al₂O₃ or AlOₓ), etc. The second insulating layer 22 can supply oxygen to the semiconductor layer 30. The second insulating layer 22 can suppress the penetration of hydrogen into the semiconductor layer 30. Thereby, good switching characteristics can be maintained even in the case where a state occurs in which, for example, the good switching characteristics of the thin film transistor 110 degrade due to the decrease of the oxygen concentration of the semiconductor layer 30.

The semiconductor layer 30 is provided in contact with the second insulating layer 22 including the compound including oxygen. The interface between the semiconductor layer 30 and the second insulating layer 22 is a high-quality interface formed between the layers of ionic oxides. Thereby, better characteristics are obtained in the semiconductor layer 30.

The third insulating layer 23 includes, for example, silicon oxide (e.g., SiO₂, i.e., SiOₓ), etc. The third insulating layer 23 can supply oxygen to the semiconductor layer 30. Thereby, oxygen can be supplied to the semiconductor layer 30 from the third insulating layer 23 as well; and good switching characteristics can be maintained.

Further, in the embodiment, the second insulating layer 22 functions as a stopper when patterning the semiconductor layer 30. Thereby, a practical process window is obtained when forming the thin film transistor 110 including the semiconductor layer 30 including the oxide.

For example, as shown in the first embodiment, in the case where a silicon nitride layer (the first insulating layer 21) is used as the gate insulating layer of the thin film transistor 110, there are cases where over-etching of the silicon nitride layer occurs and it is difficult to form the desired configuration when patterning the semiconductor layer 30. This is because the selectivity between the semiconductor layer 30 and the silicon nitride layer is low when etching. Defects such as leaks, etc., may occur if over-etching of the silicon nitride layer occurs.

In the thin film transistor 120, a layer of a metal oxide (e.g., Al₂O₃, etc.) is used as the gate insulating layer. Thereby, sufficient selectivity is obtained when patterning the semiconductor layer 30; and the etching of the semiconductor layer 30 is possible substantially without damaging the layer of the metal oxide. However, the blocking property of the metal oxide for the first gate electrode 11 formed in the foundation insulating layer 160 is low. Therefore, for example, the metallic element included in the first gate electrode 11, etc. (e.g., Cu, etc.) moves easily into the semiconductor layer 30 via the layer of the metal oxide. Thereby, there are cases where the characteristics of the semiconductor layer 30 degrade.

Conversely, in the embodiment, the foundation insulating layer 160 and the first gate electrode 11 are covered with the first insulating layer 21 that includes nitrogen and has a high blocking property. Further, the first insulating layer 21 is covered with the second insulating layer 22 that has high selectivity with respect to the semiconductor layer 30.

Thereby, the patterning of the semiconductor layer 30 is easy; and simultaneously, the movement of the metal, etc., from the lower layer can be blocked. The second insulating layer 22 can suppress the movement of hydrogen from the first insulating layer 21 toward the semiconductor layer 30.

In the embodiment, the first insulating layer 21 may include, for example, silicon nitride or silicon oxynitride. The second insulating layer 22 may include a metal compound including oxygen.

In the case where silicon oxynitride is used as the first insulating layer 21 and silicon oxynitride is used as the second insulating layer 22, the oxygen concentration of the first insulating layer 21 is set to be lower than the oxygen concentration of the second insulating layer 22. Thereby, a good blocking property of the first insulating layer 21 can be ensured. A good oxygen-supplying property of the second insulating layer 22 toward the semiconductor layer 30 can be ensured. The penetration of hydrogen into the semiconductor layer 30 can be suppressed by the second insulating layer 22.

In other words, by using the stacked structure of the first insulating layer 21 and the second insulating layer 22, the movement of hydrogen from the first insulating layer 21 toward the semiconductor layer 30 can be suppressed. Thereby, good characteristics of the semiconductor layer 30 can be maintained.

In the embodiment, the second insulating layer 22 functions as a portion of the gate insulating layer. Therefore, it is favorable for the relative dielectric constant of the second insulating layer 22 to be high. A high relative dielectric constant is obtained by using the first compound including oxygen and at least one of Al, Ti, Ta, Hf, and Zr as the second insulating layer 22. Thereby, the driving capacity of the thin film transistor 110 improves.

On the other hand, the third insulating layer 23 that covers the upper surface 30a (and the side surface 30s) of the semiconductor layer 30 may not necessarily include a material having a high relative dielectric constant. When considering, for example, patternability, reliability, etc., the third insulating layer 23 may include an appropriate material including oxygen (e.g., SiO₂, etc.). Good characteristics of the semiconductor layer 30 can be maintained by the third insulating layer 23 including an insulating material including oxygen.

In the semiconductor layer 30, the oxygen content ratios of the first portion p1 contacting the first conductive layer 41 and the second portion p2 contacting the second conductive layer 42 are smaller than the oxygen content ratio of the third portion p3 contacting the third insulating layer 23. As a result, the sheet resistances of the first portion p1 and the second portion p2 are smaller than the sheet resistance of the third portion p3. Thereby, the contact resistances of the first conductive layer 41 and the second conductive layer 42 with the semiconductor layer 30 can be reduced.

This is similar also for the thin film transistor 110 according to the first embodiment and thin film transistors according to embodiments described below.

According to the embodiment, a thin film transistor having high mobility and high thermal tolerance is obtained.

For example, an imaging element or the like is applicable as the functional element 155 of the substrate 150 of the semiconductor device 210. A CMOS image sensor (an imaging element) that uses a CMOS process may be used as the functional element 155. As downscaling of the imaging element advances, for example, the light reception surface area of the photodiode decreases; and the S/N ratio degrades. In the embodiment, an amplifier for the imaging element or a control transistor is formed in the interconnect layer on the photodiode. Thereby, both the downscaling and the S/N ratio can be ensured.

The thickness of the first insulating layer 21 is, for example, not less than 5 nanometers (nm) and not more than 50 nm.

The thickness of the second insulating layer 22 is, for example, 50 nm or less. It is favorable for the thickness of the second insulating layer 22 to be 10 nm or more. When the thickness of the second insulating layer 22 is 100 nm or more, the function as a stopper of the etching is obtained easily. When the thickness is excessively thin, for example, the stopper function degrades.

In the embodiment, at least one of the first gate electrode 11, the first conductive layer 41, and the second conductive layer 42 may include at least one of Al, Cu, W, Ta, Mo, and Ti.

In the example, the first gate electrode 11 includes a first layer 11a for the first gate electrode 11 and a second layer 11b for the first gate electrode 11. The second layer 11b is stacked with the first layer 11a. The second layer 11b is disposed between the first layer 11a and the foundation insulating layer 160. The first layer 11a includes at least one metal of Al, Cu, W, Ta, Mo, and Ti. The second layer 11b includes a material that is different from the first layer 11a. The second layer 11b includes at least one of Ta, TaN, and TiN.

For example, the first gate electrode 11 may further include a third layer 11c for the first gate electrode 11. The third layer 11c is provided between the first layer 11a and the second layer 11b. For example, at least one metal of Al and Cu may be used as the first layer 11a. TaN may be used as the second layer 11b. Ta may be used as the third layer 11c.

In the example, the first conductive layer 41 includes a first layer 41a for the first conductive layer 41 and a second layer 41b for the first conductive layer 41. The second layer 41b is stacked with the first layer 41a. The second layer 41b is disposed between the first layer 41a and the third insulating layer 23. The first layer 41a includes at least one metal of Al, Cu, W, Ta, Mo, and Ti. The second layer 41b includes a material that is different from the first layer 41a. The second layer 41b includes at least one of Ta, TaN, and TiN.

For example, the first conductive layer 41 may further include a third layer 41c for the first conductive layer 41. The third layer 41c is provided between the first layer 41a and the second layer 41b. For example, at least one metal of Al and Cu may be used as the first layer 41a. TaN may be used as the second layer 41b. Ta may be used as the third layer 41c.

In the example, the second conductive layer 42 includes a first layer 42a for the second conductive layer 42 and a second layer 42b for the second conductive layer 42. The second layer 42b is stacked with the first layer 42a. The second layer 42b is disposed between the first layer 42a and the third insulating layer 23. The first layer 42a includes at least one metal of Al, Cu, W, Ta, Mo, and Ti. The second layer 42b includes a material that is different from the first layer 42a. The second layer 42b includes at least one of Ta, TaN, and TiN.

For example, the second conductive layer 42 may further include a third layer 42c for the second conductive layer 42. The third layer 42c is provided between the first layer 42a and the second layer 42b. For example, at least one metal of Al and Cu may be used as the first layer 42a. TaN may be used as the second layer 42b. Ta may be used as the third layer 42c.

FIG. 8 is a schematic cross-sectional view showing a portion of another semiconductor device according to the second embodiment.

FIG. 8 shows a thin film transistor 121 included in the semiconductor device 211 according to the embodiment.

As shown in FIG. 8, in the thin film transistor 121 of the semiconductor device 211, the second insulating layer 22 further includes a portion 22p provided on the third portion p3 of the semiconductor layer 30. For example, the second insulating layer 22 covers the semiconductor layer 30 other than the first portion p1 and the second portion p2. For example, the second insulating layer 22 covers the side surface 30s of the semiconductor layer 30. The third insulating layer 23 covers the semiconductor layer 30 with the second insulating layer 22 interposed. Otherwise, the semiconductor device 211 may be similar to the thin film transistor 120; and a description is therefore omitted.

In the semiconductor device 211 as well, a semiconductor device having high integration and improved functions can be provided. In the semiconductor device 211, the second insulating layer 22 covers not only the lower surface of the semiconductor layer 30 but also the upper surface and the side surface 30s of the semiconductor layer 30. By covering the semiconductor layer 30 with the same material, more stable characteristics are obtained in the thin film transistor 121.

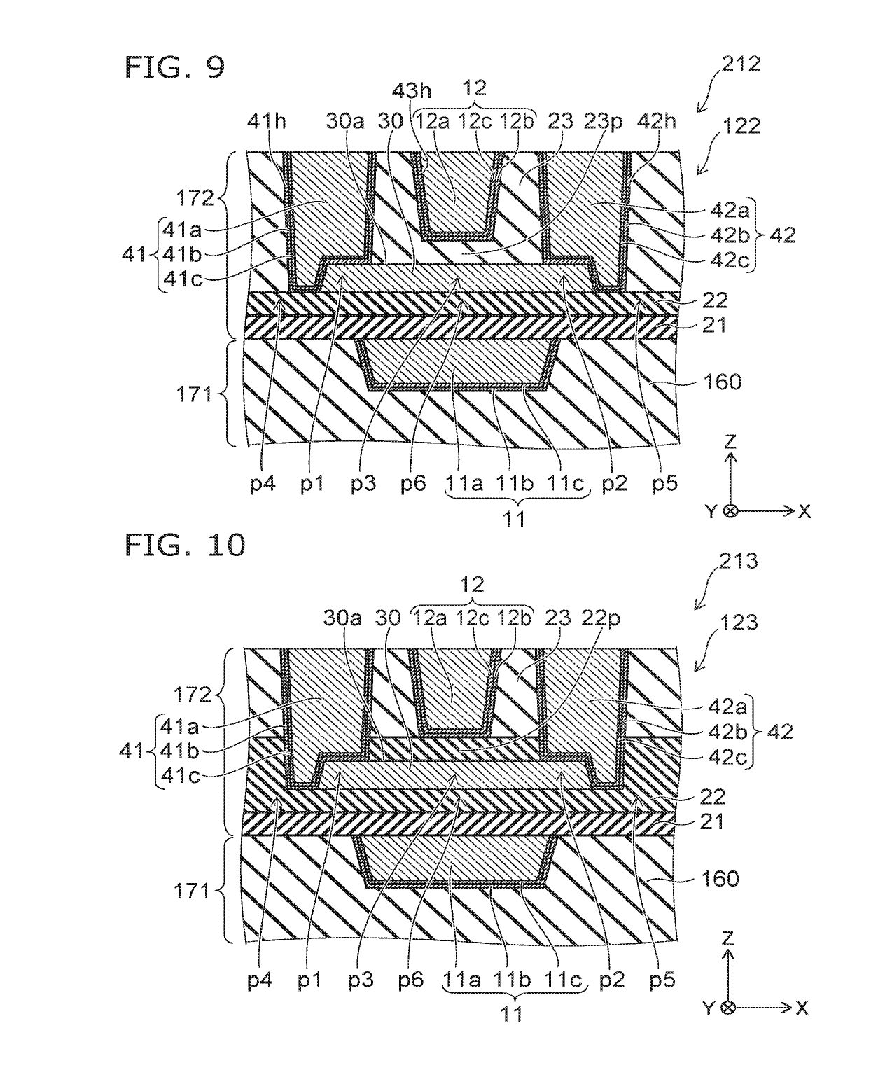

FIG. 9 is a schematic cross-sectional view showing a portion of another semiconductor device according to the second embodiment. FIG. 9 shows a thin film transistor 122 included in the semiconductor device 212 according to the embodiment.

As shown in FIG. 9, the thin film transistor 122 of the semiconductor device 212 has a double-gate structure. In other words, the thin film transistor 122 includes the first gate electrode 11 and a second gate electrode 12. Otherwise, the semiconductor device 212 may be similar to the thin film transistor 120; and a description is therefore omitted. In the semiconductor device 212, a portion of the interconnect of the first interconnect layer 171 is used as the first gate electrode 11 of the thin film transistor 122; and a portion of the interconnect of the second interconnect layer 172 is used as the second gate electrode 12.

The second gate electrode 12 is provided on the third portion p3 of the semiconductor layer 30. The third insulating layer 23 includes a portion 23p provided between the third portion p3 and the second gate electrode 12. For example, the second gate electrode 12 is formed by filling a conductive material into a third hole 43h provided in the third insulating layer 23. The third hole 43h is provided between the first hole 41h and the second hole 42h.

Because the thin film transistor 122 has the double-gate structure, more stable characteristics are obtained. In the semiconductor device 212 as well, a semiconductor device having high integration and good heat resistance can be provided.

The second gate electrode 12 may include at least one of Al, Cu, W, Ta, Mo, and Ti.

In the example, the second gate electrode 12 includes a first layer 12a for the second gate electrode 12 and a second layer 12b for the second gate electrode 12. The second layer 12b is stacked with the first layer 12a. The second layer 12b is disposed between the first layer 12a and the third insulating layer 23. The first layer 12a includes at least one metal of Al, Cu, W, Ta, Mo, and Ti. The second layer 12b includes a material that is different from the first layer 12a. The second layer 12b includes at least one of Ta, TaN, and TiN.

For example, the second gate electrode 12 may further include a third layer 12c for the second gate electrode 12. The third layer 12c is provided between the first layer 12a and the second layer 12b. For example, at least one metal of Al and Cu may be used as the first layer 12a. TaN may be used as the second layer 12b. Ta may be used as the third layer 12c.

In the case where the second gate electrode 12 is provided, the interconnect 50 (referring to FIG. 1) may be connected to the second gate electrode 12. In other words, for example, the semiconductor device 212 may further include the interconnect 50 for the second gate electrode that pierces the foundation insulating layer 160 and at least a portion of the third insulating layer 23 along the Z-axis direction (e.g., a direction intersecting the upper surface 150a of the substrate 150). For example, the interconnect 50 electrically connects the functional element 155 and the second gate electrode 12.

FIG. 10 is a schematic cross-sectional view showing a portion of another semiconductor device according to the second embodiment. FIG. 10 shows a thin film transistor 123 included in the semiconductor device 213 according to the embodiment.

As shown in FIG. 10, in the thin film transistor 123 of the semiconductor device 213, the second insulating layer 22 further includes the portion 22p provided on the third portion p3 of the semiconductor layer 30. In other words, the second insulating layer 22 includes the portion 22p provided between the third portion p3 and the second gate electrode 12. Otherwise, the semiconductor device 213 may be similar to the thin film transistor 122; and a description is therefore omitted.

For example, the second insulating layer 22 covers the semiconductor layer 30 other than the first portion p1 and the second portion p2. For example, the second insulating layer 22 covers the side surface 30s of the semiconductor layer 30. The third insulating layer 23 covers the semiconductor layer 30 with the second insulating layer 22 interposed.

In the semiconductor device 213 as well, a semiconductor device having high integration and improved functions can be provided. In the semiconductor device 213, the second insulating layer 22 covers not only the lower surface of the semiconductor layer 30 but also the upper surface and the side surface 30s of the semiconductor layer 30. The semiconductor layer 30 is covered with the same material. A double-gate structure is applied. In the thin film transistor 123, more stable characteristics are obtained.

### Third Embodiment

A thin film transistor having a top-gate structure is provided in the embodiment.

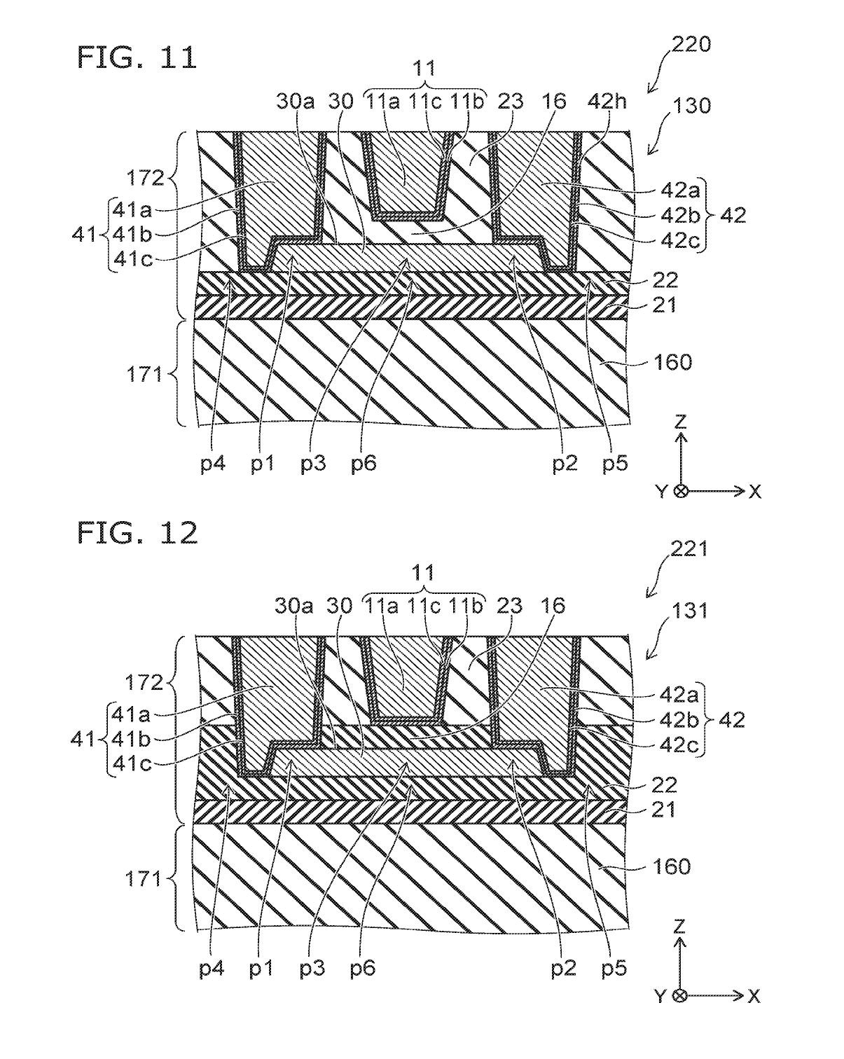

FIG. 11 is a schematic cross-sectional view showing a portion of the semiconductor device according to the second embodiment.

FIG. 11 shows a thin film transistor 130 included in the semiconductor device 220 according to the embodiment.

In the semiconductor device 220 as well, the substrate 150 described in reference to FIG. 1 is provided. In such a case as well, the substrate 150 includes the functional element 155 and has the upper surface 150a. In the semiconductor device 220 as well, the foundation insulating layer 160 is provided on the upper surface 150a. The interconnect 50 may be further provided. The substrate 150, the foundation insulating layer 160, and the interconnect 50 may be similar to those of the semiconductor device 210; and a description is therefore omitted. In the semiconductor device 220, a portion of the interconnect of the second interconnect layer 172 is used as the gate electrode 11 of the thin film transistor 130. The portion that is positioned on the foundation insulating layer 160 will now be described.

The semiconductor device 220 includes the first insulating layer 21, the second insulating layer 22, the semiconductor layer 30, a gate insulating layer 16, the first gate electrode 11, the first conductive layer 41, the second conductive layer 42, and the third insulating layer 23 in addition to the substrate 150, the foundation insulating layer 160, and the interconnect 50. For example, the semiconductor layer 30, the gate insulating layer 16, the gate electrode 11, the first conductive layer 41, the second conductive layer 42, and the third insulating layer 23 are included in the thin film transistor 130.

The first insulating layer 21 is provided on the foundation insulating layer 160. The first insulating layer 21 includes silicon and nitrogen. The first insulating layer 21 includes, for example, silicon nitride or silicon oxynitride.

The second insulating layer 22 is provided on the first insulating layer 21. The second insulating layer 22 includes the fourth portion p4, the fifth portion p5, and the sixth portion p6. The fifth portion p5 is separated from the fourth portion p4 in the first direction (e.g., the X-axis direction) in the X-Y plane (a plane parallel to the upper surface 150a). The sixth portion p6 is provided between the fourth portion p4 and the fifth portion p5. In such a case as well, the second insulating layer 22 includes oxygen and at least one of Al, Ti, Ta, Hf, and Zr.

The semiconductor layer 30 contacts a portion of the second insulating layer 22. The semiconductor layer 30 includes the first portion p1, the second portion p2, and the third portion p3. The second portion p2 is separated from the first portion p1 in the first direction (the X-axis direction). The third portion p3 is provided between the first portion p1 and the second portion p2. The semiconductor layer 30 is an oxynitride including In, Ga, and Zn.

In such a case as well, when projected onto the X-Y plane, the first portion p1 is disposed between the third portion p3 and the fourth portion p4. When projected onto the X-Y plane, the second portion p2 is disposed between the third portion p3 and the fifth portion p5. When projected onto the X-Y plane, the third portion p3 overlaps the sixth portion p6.

The gate insulating layer 16 is provided on the sixth portion p6 of the semiconductor layer 30. The gate insulating layer 16 includes metal and oxygen. The gate insulating layer 16 may include, for example, oxygen and at least one of Al, Ti, Ta, Hf, and Zr.

The first gate electrode 11 is provided on the gate insulating layer 16. In other words, the gate insulating layer 16 is provided between the first gate electrode 11 and the third portion p3 of the semiconductor layer 30.

The first conductive layer 41 contacts the first portion p1 and the fourth portion p4. The second conductive layer 42 contacts the second portion p2 and the fifth portion p5.

The third insulating layer 23 covers a portion of the semiconductor layer 30 other than the first portion p1 and the second portion p2. The third insulating layer 23 may be continuous with the gate insulating layer 16. The third insulating layer 23 may cover the third portion p3 of the semiconductor layer 30 with the gate insulating layer 16 interposed. The third insulating layer 23 may further cover the side surface 30s of the semiconductor layer 30. The third insulating layer 23 includes oxygen and at least one of Si, Al, Ti, Ta, Hf, and Zr.

In the embodiment, the foundation insulating layer 160 and the first gate electrode 11 are covered with the first insulating layer 21 that includes nitrogen and has a high blocking property. Further, the first insulating layer 21 is covered with the second insulating layer 22 that has high selectivity with respect to the semiconductor layer 30. Thereby, good patterning of the semiconductor layer 30 can be realized; and simultaneously, the movement of the metal, etc., from the lower layer can be blocked. The movement of hydrogen from the first insulating layer 21 toward the semiconductor layer 30 can be suppressed by the second insulating layer 22. A good oxygen-supplying property of the second insulating layer 22 toward the semiconductor layer 30 can be ensured. Thereby, good characteristics of the semiconductor layer 30 can be maintained.

In the embodiment, it is favorable for the relative dielectric constant of the gate insulating layer 16 to be high. A high relative dielectric constant is obtained by using a compound including oxygen and at least one of Al, Ti, Ta, Hf, and Zr as the gate insulating layer 16. Thereby, the driving capacity of the thin film transistor 120 improves.

According to the embodiment, a thin film transistor having high mobility, high reliability, and improved functions is obtained. In the embodiment as well, a thin film transistor having high integration and high thermal tolerance can be provided.

In the example, the material of the third insulating layer 23 may be the same as the material of the gate insulating layer 16. In such a case, the third insulating layer 23 and the gate insulating layer 16 are continuous; and a boundary is not observed. The portion of the insulating layer of this material positioned between the semiconductor layer 30 and the first conductive layer 41 is used as the gate insulating layer 16. The remaining portion is used as the third insulating layer 23.

FIG. 12 is a schematic cross-sectional view showing a portion of another semiconductor device according to the third embodiment.

FIG. 12 shows a thin film transistor 131 included in the semiconductor device 221 according to the embodiment.

As shown in FIG. 12, the gate insulating layer 16 is continuous with the second insulating layer 22 in the thin film transistor 131. For example, the material of the gate insulating layer 16 is the same as the material of the second insulating layer 22. For example, the gate insulating layer 16 and the second insulating layer 22 include a compound including oxygen and at least one of Al, Ti, Ta, Hf, and Zr. A high relative dielectric constant and a high etching stopper property are obtained.

More stable characteristics of the thin film transistor 131 are obtained because the lower surface and upper surface of the semiconductor layer 30 are covered with the same material. In the semiconductor device 211 as well, a semiconductor device having high integration and improved functions can be provided.

### Fourth Embodiment

The embodiment relates to a method for manufacturing the semiconductor device according to the first embodiment.

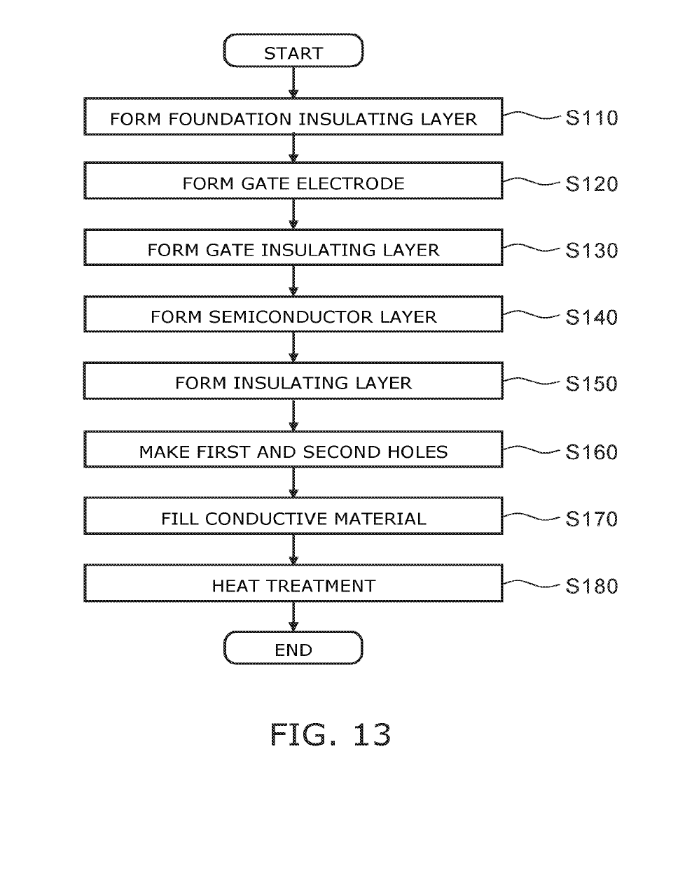

FIG. 13 is a flowchart showing the method for manufacturing the semiconductor device according to the fourth embodiment.

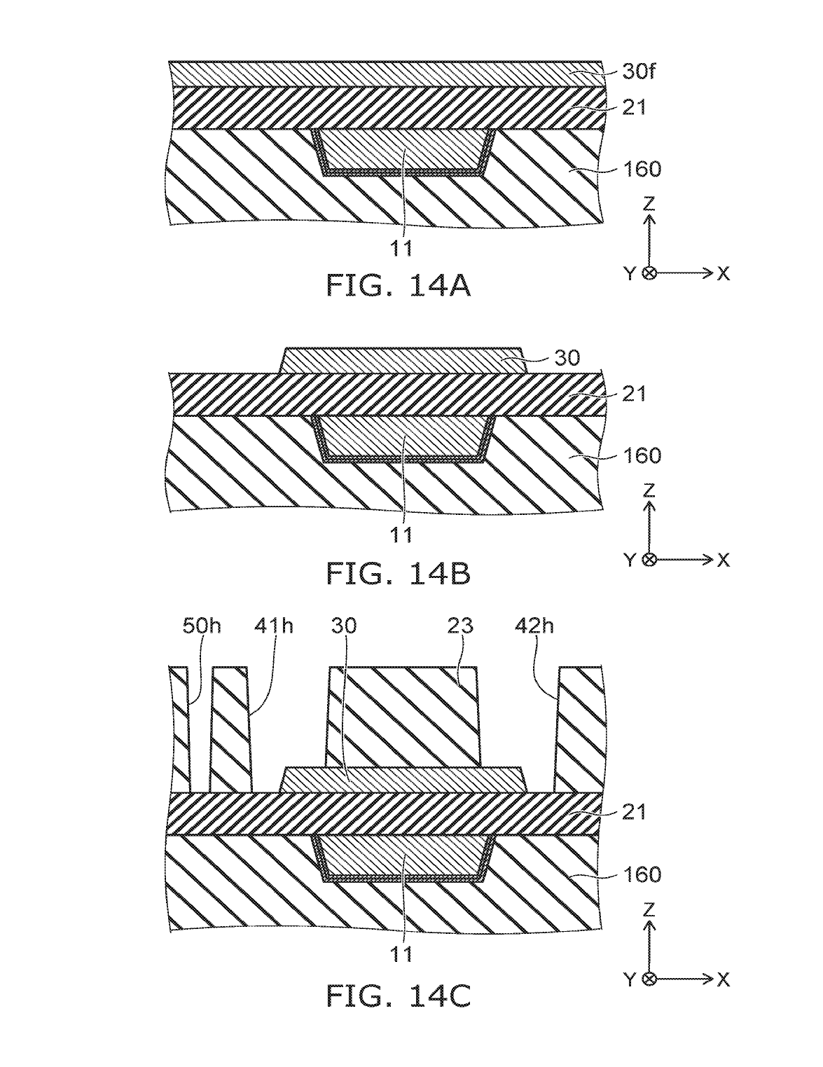

FIG. 14A to FIG. 14C are schematic cross-sectional views in order of the processes, showing the method for manufacturing the semiconductor device according to the fourth embodiment.

In the manufacturing method as shown in FIG. 13, the foundation insulating layer 160 is formed on the upper surface 150a of the substrate 150, which includes the functional element 155 and has the upper surface 150a (step S110).

The gate electrode 11 is formed on a portion of the foundation insulating layer 160 (step S120).

The first insulating layer 21 (a gate insulating layer) is formed to cover the gate electrode 11 and the foundation insulating layer 160 (step S130). In the case where the gate insulating layer has a two-layer structure, the second insulating layer 22 is formed on the first insulating layer 21. In the example of the second embodiment, the second insulating layer 22 that includes oxygen and at least one of Al, Ti, Ta, Hf, and Zr is formed on the first insulating layer 21 including silicon and nitrogen.

As shown in FIG. 14A, a semiconductor film 30f of an oxynitride including In, Ga, and Zn is formed on the first insulating layer 21. For example, the oxynitride semiconductor layer is formed using reactive sputtering. The film formation atmosphere when sputtering is, for example, a mixed atmosphere including argon, oxygen, and nitrogen. The carrier density inside the oxynitride semiconductor can be controlled by the proportions of argon, oxygen, and nitrogen. Also, the formation is possible using various thin film formation methods such as PLD, reactive sputtering, CVD, spin coating, etc. For example, the oxynitride semiconductor thus formed has an amorphous structure, a microcrystal structure, and a polycrystalline structure. For example, the film properties of the oxynitride semiconductor can be evaluated by observing the structure using high-magnification TEM.

As shown in FIG. 14B, the semiconductor layer 30 is formed from the semiconductor film 30f by patterning the semiconductor film 30f (step S140). For example, dry etching is used to pattern the semiconductor film 30f. For example, a gas including chlorine is used in the dry etching. A gas including boron trichloride may be used.

The insulating layer 23 that includes oxygen and at least one of Si, Al, Ti, Ta, Hf, and Zr is formed on the semiconductor layer 30 and on an insulating layer 24 (step S150). The insulating layer 23 functions as a protective film covering the oxynitride semiconductor layer. The insulating layer 23 may be, for example, an inter-layer insulating layer (a SiOₓ film) formed using PCVD. For example, the film formation may be performed in a mixed atmosphere including silane and nitrous oxide or in a mixed atmosphere including TEOS (tetraethoxysilane) and oxygen (or ozone).

As shown in FIG. 14C, the first hole 41h that reaches the semiconductor layer 30 from the upper surface of the insulating layer 23, and the second hole 42h that reaches the semiconductor layer 30 from the upper surface of the insulating layer 23 and is separated from the first hole 41h are made (step S160). For example, dry etching is used to make the first hole 41h and the second hole 42h. For example, a gas including at least one of tetrafluoromethane, trifluoromethane, and oxygen is used in the dry etching.

A conductive material is filled into the first hole 41h and the second hole 42h (step S170). The first conductive layer 41 is formed of the conductive material filled into the first hole 41h. The second conductive layer 42 is formed of the conductive material filled into the second hole 42h. Thus, a thin film transistor (e.g., the thin film transistor 110) that includes the semiconductor layer 30 is formed.

The formation of the first hole 41h and the second hole 42h recited above (step S160) may include making, from the upper surface of the insulating layer 23, the third hole 43h that is separated from the semiconductor layer 30. The third hole 43h is made between the first hole 41h and the second hole 42h. The filling of the conductive material (step S170) may include filling the conductive material into the third hole 43h. Thereby, the second gate electrode 12 can be formed.

Then, heat treatment is performed for the substrate 150 in which the thin film transistor 110 is formed (step S180). For example, heat treatment inside a clean oven or a quartz furnace is performed. The heat treatment is performed at 200° C. to 400° C., and favorably 350 to 400° C. The atmosphere is ambient air or a nitrogen atmosphere.

According to the manufacturing method according to the embodiment, a method for manufacturing a semiconductor device having high integration and improved functions can be provided.

In the embodiment as shown in FIG. 14C, a hole (an interconnect hole 50h) for the interconnect 50 may be further provided. In other words, the formation of the first hole 41h and the second hole 42h (step S160) may include making the interconnect hole 50h where at least a portion of the interconnect 50 electrically connecting the functional element 155 and the thin film transistor is formed. Then, the filling of the conductive material (step S170) may include filling a conductive material into the interconnect hole 50h. Thereby, at least a portion of the interconnect 50 can be formed.

### Fifth Embodiment

The embodiment relates to a method for manufacturing the semiconductor device according to the third embodiment.

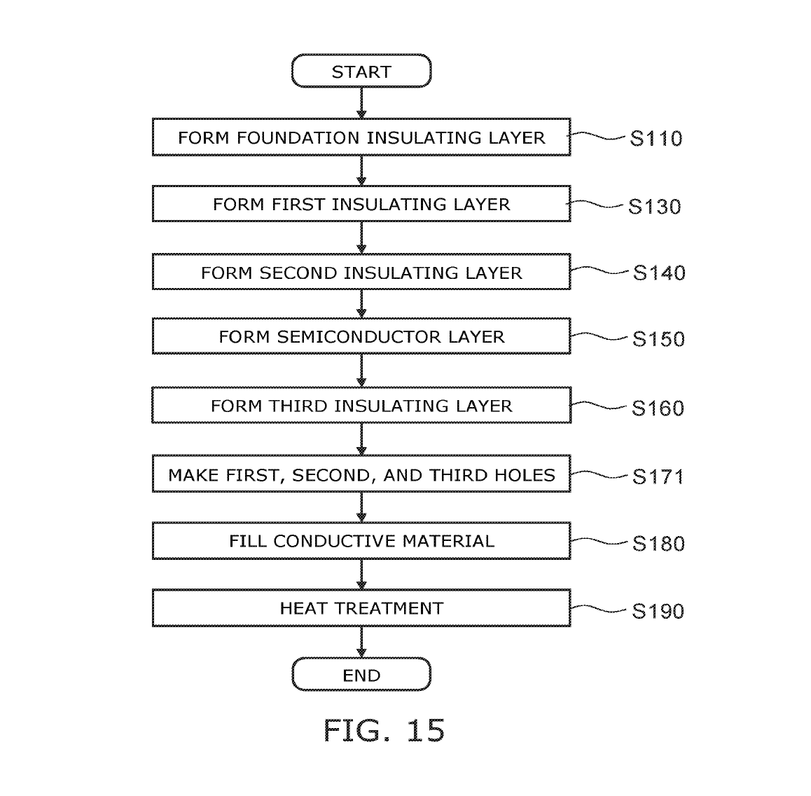

FIG. 15 is a flowchart showing the method for manufacturing the semiconductor device according to the fifth embodiment.

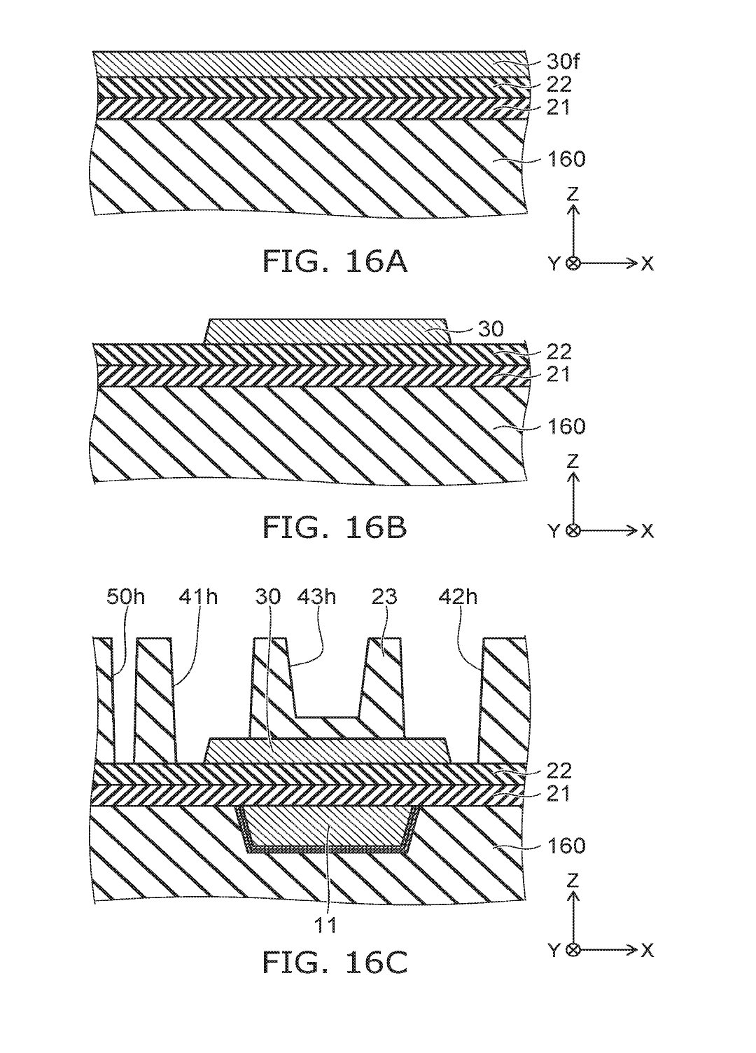

FIG. 16A to FIG. 16C are schematic cross-sectional views in order of the processes, showing the method for manufacturing the semiconductor device according to the fifth embodiment.

In the manufacturing method as shown in FIG. 15, the foundation insulating layer 160 is formed on the upper surface 150a of the substrate 150, which includes the functional element 155 and has the upper surface 150a (step S110).

The first insulating layer 21 that includes silicon and nitrogen is formed on the foundation insulating layer 160 (step S130).

The second insulating layer 22 that includes oxygen and at least one of Al, Ti, Ta, Hf, and Zr is formed on the first insulating layer 21 (step S140).

As shown in FIG. 16A, the semiconductor film 30f of an oxynitride including In, Ga, and Zn is formed on the second insulating layer 22.

As shown in FIG. 16B, the semiconductor layer 30 is formed from the semiconductor film 30f by patterning the semiconductor film 30f using the second insulating layer 22 as a stopper (step S150). In such a case as well, for example, dry etching is used to pattern the semiconductor film 30f. For example, a gas including chlorine is used in the dry etching. A gas including boron trichloride may be used.

The third insulating layer 23 that includes oxygen and at least one of Si, Al, Ti, Ta, Hf, and Zr is formed on the semiconductor layer 30 and on the second insulating layer 22 (step S160). For example, a portion of the third insulating layer 23 on the semiconductor layer 30 is used as the gate insulating layer 16.

As shown in FIG. 16C, the first hole 41h that reaches the semiconductor layer 30 from the upper surface of the third insulating layer 23, the second hole 42h that reaches the semiconductor layer 30 from the upper surface of the third insulating layer 23 and is separated from the first hole 41h, and the third hole 43h that is separated from the semiconductor layer 30 between the first hole 41h and the second hole 42h are made (step S171). For example, dry etching is used to make the first hole 41h, the second hole 42h, and the third hole 43h. In such a case as well, for example, a gas including at least one of tetrafluoromethane, trifluoromethane, and oxygen is used in the dry etching.

A conductive material is filled into the first hole 41h, the second hole 42h, and the third hole 43h (step S180). The first conductive layer 41 is formed of the conductive material filled into the first hole 41h. The second conductive layer 42 is formed of the conductive material filled into the second hole 42h. The first gate electrode 11 is formed of the conductive material filled into the third hole 43h. Thus, a thin film transistor (e.g., the thin film transistor 120) that includes the semiconductor layer 30 is formed.

According to the manufacturing method according to the embodiment, a method for manufacturing a semiconductor device having high integration and improved functions can be provided.

As shown in FIG. 16C, in such a case as well, the formation of the first hole 41h and the second hole 42h (step S171) may include making the interconnect hole 50h where at least a portion of the interconnect 50 that electrically connects the functional element 155 and the thin film transistor is formed. Then, the filling of the conductive material (step S180) may include filling a conductive material into the interconnect hole 50h. Thereby, at least a portion of the interconnect 50 can be formed.

In the first to fourth embodiments, in the case where the insulating layer 22 and the insulating layer 23 include silicon oxide, at least one of these layers may include a TEOS film. At least one of the second insulating layer 22 and the third insulating layer 23 may include a porous film. The porous film includes, for example, SiOC. By using the porous film, for example, the parasitic capacitance between the interconnects can be reduced.

Then, heat treatment is performed for the substrate 150 in which the thin film transistor 110 is formed (step S190). For example, heat treatment inside a clean oven or a quartz furnace is performed. The heat treatment is performed at 200° C. to 400° C., and favorably 350 to 400° C. The atmosphere is ambient air or a nitrogen atmosphere.

According to the embodiments, a semiconductor device and a method for manufacturing the semiconductor device having high integration and improved functions can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the invention is not limited to these specific examples. For example, one skilled in the art may similarly practice the invention by appropriately selecting specific configurations of components included in the semiconductor device such as the substrate, the functional element, foundation insulating layer, the first gate electrode, the second gate electrode, the first to third insulating layers, the gate insulating layers, the first conductive layer, the second conductive layer, the interconnect, the first to third interconnects, and inter-layer insulating layer, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all semiconductor devices, methods for manufacturing the semiconductor devices and imaging devices practicable by an appropriate design modification by one skilled in the art based on the semiconductor devices, the methods for manufacturing the semiconductor devices and the imaging devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a substrate having a major surface; and
a thin film transistor provided on the substrate, the thin film transistor including
an oxynitride semiconductor layer including a first portion, a second portion, and a third portion, the second portion being separated from the first portion in a first direction parallel to the major surface, the third portion being provided between the first portion and the second portion, the oxynitride semiconductor layer including indium, gallium, zinc, and nitrogen, a nitrogen content of the oxynitride semiconductor layer being 2 atomic % or less, a gallium content of the oxynitride semiconductor layer being more than the nitrogen content,
a first conductive layer electrically connected to the first portion,
a second conductive layer electrically connected to the second portion,
a first gate electrode separated from the third portion in a second direction intersecting the first direction, and
a first insulating layer provided between the third portion and the first gate electrode.

2. The device according to claim 1, wherein a proportion of a number of nitrogen atoms is not more than 3.3 atomic % of the sum of a number of oxygen atoms and the number of nitrogen atoms in the oxynitride semiconductor layer.

3. The device according to claim 1, wherein the oxynitride semiconductor layer has an amorphous structure.

4. The device according to claim 1, wherein the oxynitride semiconductor layer includes a bond of indium and nitrogen, a bond of zinc and nitrogen, and a bond of gallium and nitrogen.

5. The device according to claim 4, wherein a proportion of the bond of gallium and nitrogen is larger than a proportion of the bond of indium and nitrogen and larger than a proportion of the bond of zinc and nitrogen in the oxynitride semiconductor layer.

6. The device according to claim 1, wherein the oxynitride semiconductor layer includes a bond of indium, oxygen, and nitrogen, a bond of zinc, oxygen, and nitrogen, and a bond of gallium, oxygen, and nitrogen.

7. The device according to claim 6, wherein a proportion of the bond of gallium, oxygen, and nitrogen is larger than a proportion of the bond of indium, oxygen, and nitrogen and larger than a proportion of the bond of zinc, oxygen, and nitrogen in the oxynitride semiconductor layer.

8. The device according to claim 1, wherein an oxygen content of the third portion of the oxynitride semiconductor layer is more than oxygen contents of the first portion and the second portion thereof.

9. The device according to claim 1, wherein the first insulating film includes a compound including silicon and nitrogen.

10. The device according to claim 1, wherein
the thin film transistor further includes a second insulating layer including an oxide, and
the second insulating layer is provided between the first insulating layer and the oxynitride semiconductor layer.

11. The device according to claim 10, wherein the second insulating layer covers the oxynitride semiconductor layer.

12. The device according to claim 11, wherein
the thin film transistor further includes a second gate electrode provided on the third portion with the second insulating layer interposed, and
the third portion is positioned between the first gate electrode and the second gate electrode.

13. The device according to claim 10, wherein the second insulating layer includes a compound including oxygen and at least one of Al, Ti, Ta, Hf, and Zr.

14. The device according to claim 10, wherein
the first insulating film is a silicon oxynitride film, and
the second insulating film is a silicon oxynitride film having a higher oxygen concentration than the first insulating film.

15. The device according to claim 11, wherein the thin film transistor further includes a third insulating film provided on the second insulating film, the third insulating film including oxygen.

16. The device according to claim 1, wherein
the thin film transistor further includes a third insulating film covering the third portion and including oxygen, and
the third portion is positioned between the first insulating film and the third insulating film.

17. The semiconductor device according to claim 16, wherein the third insulating film includes a compound including oxygen and at least one of Si, Al, Ti, Ta, Hf, and Zr.

18. The device according to claim 16, wherein the thin film transistor further includes a second gate electrode provided, with a third insulating film interposed, on a side of the third portion opposite to the first gate electrode.

19. A semiconductor device, comprising:
a substrate including a functional element and having a major surface; and
a thin film transistor provided on the substrate, the thin film transistor including
an oxynitride semiconductor layer including a first portion, a second portion, and a third portion, the second portion being separated from the first portion in a first direction parallel to the major surface, the third portion being provided between the first portion and the second portion, the oxynitride semiconductor layer including indium, gallium, zinc, and nitrogen, a nitrogen content of the oxynitride semiconductor layer being 2 atomic % or less, a gallium content of the oxynitride semiconductor layer being more than the nitrogen content,
a first conductive layer electrically connected to the first portion,
a second conductive layer electrically connected to the second portion,
a gate electrode separated from the third portion in a second direction intersecting the first direction,
a first insulating layer provided on a side of the third portion opposite to the gate electrode, the first insulating layer including a compound including silicon and nitrogen,
a second insulating film provided between the third portion and the first insulating film, the second insulating film including a compound including oxygen and at least one of Al, Ti, Ta, Hf, and Zr, and
a third insulating film provided between the third portion and the gate electrode.

20. An imaging device, comprising:
a substrate including a functional element including an imaging unit; and
a thin film transistor provided on the substrate, the thin film transistor including
an oxynitride semiconductor layer including a first portion, a second portion, and a third portion, the second portion being separated from the first portion in a first direction parallel to a major surface of the substrate, the third portion being provided between the first portion and the second portion, the oxynitride semiconductor layer including indium, gallium, zinc, and nitrogen, a nitrogen content of the oxynitride semiconductor layer being 2 atomic % or less, a gallium content of the oxynitride semiconductor layer being more than the nitrogen content,
a first conductive layer electrically connected to the first portion,
a second conductive layer electrically connected to the second portion,
a first gate electrode separated from the third portion in a second direction intersecting the first direction, and
a first insulating layer provided between the third portion and the first gate electrode.
